(19) United States
(12) Patent Application Publication
(10) Pub. No.: US 2006/0141751 A1
(43) Pub. Date: Jun. 29, 2006

(54) Method for making a silicon dioxide layer on a silicon substrate by anodic oxidation

(75) Inventors: Wei-Jian Liao, Tu-Cheng (TW); Hsin-Ho Lee, Tu-Cheng (TW)

Correspondence Address: MORRIS MANNING & MARTIN LLP, 1600 ATLANTA FINANCIAL CENTER, 3343 PEACHTREE ROAD, NE, ATLANTA, GA, 30326-1044, US

(73) Assignee: HON HAI Precision Industry CO., LTD., Tu-Chen City (TW)

(21) Appl. No.: 11/302,755

(22) Filed: Dec. 14, 2005

(30) Foreign Application Priority Data
Dec. 25, 2004 (CN) 200410091899.9

(51) Int. Cl. H01L 21/479

(52) U.S. Cl. 438/466; 438/787; 438/770

(57) ABSTRACT

A method for forming silicon dioxide layer on a silicon substrate by anodic oxidation includes: providing a silicon substrate which has a polished face; providing an anodic oxidation apparatus which is filled with an electrolyte; providing a platinum piece and placing the platinum piece in the electrolyte as a cathode; placing the silicon substrate in the electrolyte as an anode with the polished surface of the silicon substrate facing to the cathode; applying a direct current to the cathode and the anode and irradiating the electrolyte with ultraviolet light for a predetermined period of time; taking out the silicon substrate and getting a finished silicon dioxide layer formed on the silicon substrate after cleaning, drying and cooling. The method can increase the reaction rate, and the silicon dioxide layer so formed has a uniform thickness and high purity.

### FIELD OF THE INVENTION

The present invention relates to a method for making a silicon dioxide layer, and more particularly to a method for making a silicon dioxide layer on a silicon substrate by anodic oxidation.

### BACKGROUND

In microelectronics, high quality ultra-thin gate oxides are needed for improving performance of thin film transistors (TFTs) when the size of the device is small and the device includes ultra large scale integration (ULSI) circuits. In semiconductor processing, the thin-gate oxides are mainly comprised of a silicon dioxide layer directly formed on a silicon substrate.

Conventional methods for forming a silicon dioxide layer in the fabrication of an integrated circuit include thermal oxidation, chemical vapor deposition (CVD), plasma enhanced chemical vapor deposition (PECVD), and liquid phase deposition (LPD). The thermal oxidation method must be carried out at a high temperature, and is a time-consuming process. These shortcomings of thermal oxidation can be overcome by employing the methods of CVD, PECVD or LPD instead. However, the CVD, PECVD and LPD methods also have certain shortcomings. For example, these methods may also be time-consuming; and it is difficult to form an oxide layer having a uniform thickness using these methods.

High quality thin-gate oxides became possible when anodic oxidation was invented, wherein a silicon dioxide layer is formed on a silicon substrate. In 1956, A. Uhlir and D. R. Turner first discovered that a porous silicon dioxide layer could be formed on a silicon substrate by an anodic oxidation method. The method includes steps of: providing a silicon substrate, a metallic anode, a cathode, and an anodic oxidation apparatus having a vessel; introducing hydrofluoric acid into the vessel; placing the metallic anode and the cathode in the hydrofluoric acid and positioning the silicon substrate between the metallic anode and the cathode; and applying a direct current to the metallic anode and the cathode. Thereby, a porous silicon dioxide layer is formed on the silicon substrate.

This method can be implemented at a relatively low temperature (room temperature), and problems including cracking and the impurity-redistribution effect of the silicon substrate are eliminated. The silicon dioxide layer has an even thickness, because the porous silicon dioxide layer formed is capable of self-filling the voids. However, the method is also time-consuming. In addition, the metallic anode may be partially dissolved in the hydrofluoric acid. If this happens, the silicon dioxide layer may be contaminated by the metal ions dissolved in the electrolyte.

In order to overcome the above problems, another method for forming a silicon dioxide layer on a silicon substrate has been developed. The method includes steps of conducting an electrolytic reaction at room temperature such that a silicon dioxide layer is formed on a silicon substrate acting as an anode, in which pure water is used as an electrolyte and a platinum piece is used as a cathode, and the electrolytic reaction is carried out with a current density ranging between 1 and 100 μA/cm²; removing the silicon substrate from the electrolyte; and heating the silicon substrate in an inert gas atmosphere at a temperature of 700° C.-1000° C. Because the electrolyte is pure water and the silicon substrate itself is directly used as an anode, the silicon dioxide layer can be formed on the silicon substrate without contamination of any other metallic elements dissolved into the electrolyte. However, the method is still time-consuming.

What is needed, therefore, is a method for making a silicon dioxide layer on a silicon substrate, wherein the process has an increased reaction rate, and a silicon dioxide layer having an uniform thickness can be obtained.

### SUMMARY

The present invention provides a method for forming a silicon dioxide layer on a silicon substrate by anodic oxidation. A preferred embodiment of the method includes: providing a silicon substrate which has a polished face; providing an anodic oxidation apparatus which is filled with an electrolyte; providing a platinum piece and placing the platinum piece in the electrolyte as a cathode; placing the silicon substrate in the electrolyte as an anode with the polished surface of the silicon substrate facing to the cathode; applying a direct current to the cathode and the anode and irradiating the electrolyte with ultraviolet light for a predetermined period of time; taking out the silicon substrate and getting a finished silicon dioxide layer formed on the silicon substrate after cleaning, drying and cooling.

Compared with conventional methods for making the silicon dioxide layer on a silicon substrate, the preferred method of the present invention using ultraviolet light to irradiate de-ionized water of the electrolyte when the anodic oxidation is processing. Ions produced by electrolyzing the de-ionized water can attain an additional energy when the ultraviolet light uniformly irradiating the de-ionized water. Thus the hydroxyl ions can be easily and quickly reacted with the plurality of silicon atoms on the polish surface of the silicon substrate to produce a silicon dioxide layer, and silicon-oxygen bonds of the silicon dioxide layer are formed perfectly for decreasing any defects such as pinholes or cracks between the silicon dioxide layer and the silicon substrate. Therefore, the silicon dioxide layer has a high purity and a uniform thickness, and a reaction rate of the anodic oxidation is improved.

Other advantages and novel features will become more apparent from the following detailed description of preferred embodiments when taken in conjunction with the accompanying drawings.

### BRIEF DESCRIPTION OF THE DRAWINGS

Many aspects of the method for making a silicon dioxide layer on a silicon substrate by anodic oxidation can be better understood with reference to the following drawings. The components in the drawings are not necessarily to scale, the emphasis instead being placed upon clearly illustrating the principles of the present method. Moreover, in the drawings, like reference numerals designate corresponding parts throughout the several views.

FIG. 1 is a flow chart of a method for making a silicon dioxide layer on a silicon substrate by anodic oxidation according to a preferred embodiment of the present invention.

FIG. 2 is a schematic, cross-sectional view of an anodic oxidation apparatus for making a silicon dioxide layer on a silicon substrate by anodic oxidation according to the preferred embodiment of the present invention.

### DETAILED DESCRIPTION OF THE PREFERRED EMBODIMENTS

Reference will now be made to the drawings to describe preferred embodiments of the present invention in detail.

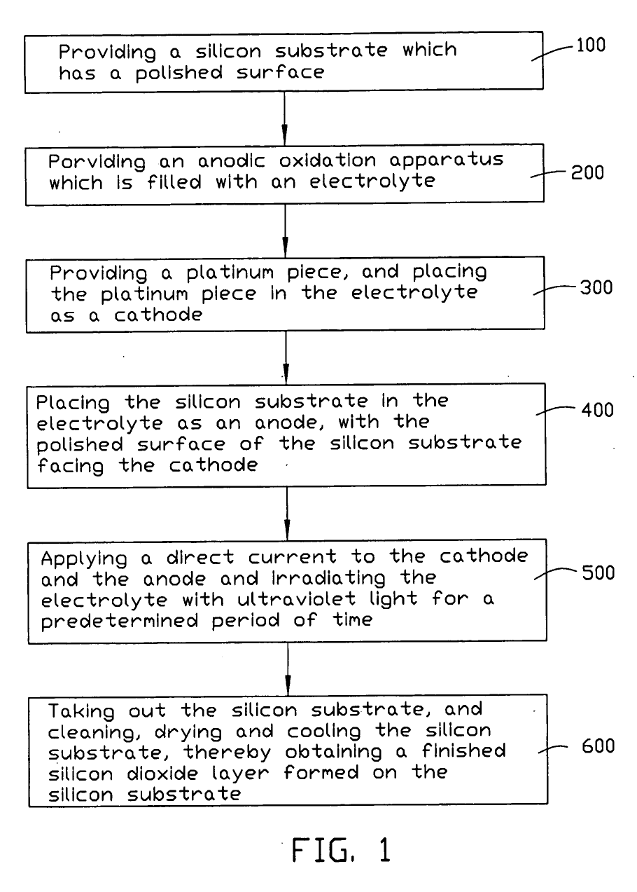

FIG. 1 is a flow chart of a method for making a silicon dioxide thin layer on a silicon substrate by anodic oxidation in accordance with a preferred embodiment of the present invention. The method includes the steps of:

step 100: providing a clean silicon substrate which has a polished surface;

step 200: providing an anodic oxidation apparatus which is filled with an electrolyte;

step 300: providing a platinum piece, and placing the platinum piece in the anodic oxidation apparatus as a cathode;

step 400: placing the silicon substrate in the anodic oxidation apparatus as an anode, with the polished surface of the silicon substrate facing the cathode;

step 500: applying a direct current to the cathode and the anode and irradiating the electrolyte with ultraviolet light for a predetermined period of time; and

step 600: taking out the silicon substrate, and cleaning, drying and cooling the silicon substrate, thereby obtaining a finished silicon dioxide layer formed on the silicon substrate.

In step 100, a surface of the silicon substrate is polished by a polisher, and then the silicon substrate is cleaned with pure deionized water.

In step 200, the anodic oxidation apparatus has an anodic oxidation vessel. Pure deionized water is introduced into the anodic oxidation vessel, for use as an electrolyte.

In step 300, the platinum piece is used as a cathode when most of the platinum piece is submerged in the deionized water in the anodic oxidation apparatus.

In step 500, an electrolytic reaction is carried out, with a current density of the direct current being in the range from 1 to 100 μA/cm². Preferably, the predetermined period of time for the electrolytic reaction is in the range from 5 to 30 minutes. Accordingly, a thickness of silicon dioxide formed on the silicon substrate is in the range from 10 to 100 nanometers. Ions produced by electrolyzing the deionized water can attain an additional energy when the ultraviolet light uniformly irradiates the deionized water. Thus, the hydroxyl ions can be easily and quickly reacted with a multiplicity of silicon atoms on the polished surface of the silicon substrate to produce a silicon dioxide layer having a uniform thickness.

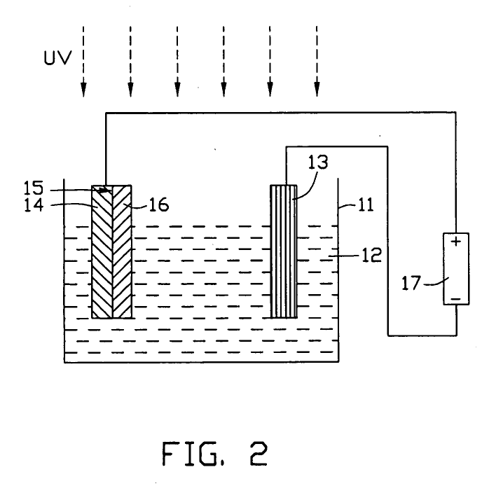

FIG. 2 shows an anodic oxidation apparatus 10 for making a silicon dioxide layer on a silicon substrate by anodic oxidation. The anodic oxidation apparatus 10 includes an anodic oxidation vessel 11, an electrolyte 12 filled in the anodic oxidation vessel 11, and a direct current (DC) power source 17 which can provide a steady direct current. In the preferred embodiment of the present invention, the electrolyte 12 is pure deionized water, a silicon substrate 14 having a polished surface 15 is used as an anode and is electrically connected to a positive terminal of the DC power source 17, and a platinum piece 13 is used as a cathode and is electrically connected to a negative terminal of the DC power source 17. Most portions of the platinum piece 13 and the silicon substrate 14 are both dipped in the electrolyte 12, with the polished surface 15 of the silicon substrate 14 facing the platinum piece 13.

When the DC power source 17 is turn on and the electrolytic reaction is carried out, ultraviolet light irradiates the electrolyte 12 uniformly. The pure deionized water of the electrolyte 12 is electrolyzed to produce a multiplicity of hydrogen ions (H⁺) and hydroxyl ions (OH⁻) which have a high oxidation capability. Because the silicon substrate 14 is connected to the positive terminal of the DC power source 17, the hydroxyl ions are pulled into the polished surface 15 of the silicon substrate 14 by a positive voltage produced by the DC power source 17, and then the hydroxyl ions oxidize a multiplicity of silicon atoms to produce a silicon dioxide layer 16 on the polished surface 15 of the silicon substrate 14.

Finally, while the present invention has been described with reference to particular embodiments, the description is illustrative of the invention and is not to be construed as limiting the invention. Therefore, various modifications can be made to the embodiments by those skilled in the art without departing from the true spirit and scope of the invention as defined by the appended claims.

What is claimed is:

1. A method for forming a silicon dioxide layer on a silicon substrate by anodic oxidation, the method comprising the steps of:
providing a silicon substrate which has a polished face;
providing an anodic oxidation apparatus which is filled with an electrolyte;
providing a platinum piece, and placing the platinum piece in the electrolyte as a cathode;
placing the silicon substrate in the electrolyte as an anode, with the polished surface of the silicon substrate facing the cathode;
applying a direct current to the cathode and the anode and irradiating the electrolyte with ultraviolet light for a predetermined period of time; and
taking out the silicon substrate, and cleaning, drying and cooling the silicon substrate, thereby obtaining a finished silicon dioxide layer formed on the silicon substrate.

2. The method as recited in claim 1, wherein the electrolyte comprises deionized water.

3. The method as recited in claim 1, wherein the predetermined period of time is in the range from 5˜30 minutes.

4. The method as recited in claim 1, wherein a current density of the direct current is in the range from 1 to 100 μA/cm².

5. The method as recited in claim 1, wherein a thickness of silicon dioxide layer is in the range from 10 to 100 nanometers.

6. A method for anodic oxidizing a substrate, comprising the steps of:
preparing a substrate to be anodic oxidized for using as an anode;
placing said substrate and a cathode in an electrolyte;
electrifying said substrate and said cathode through said electrolyte; and
forcefully exciting particles of said electrolyte during said electrifying step.

7. The method as recited in claim 6, wherein said particle-exciting step comprises the step of irradiating said electrolyte by means of ultraviolet light for a predetermined period of time.

8. The method as recited in claim 6, wherein said electrolyte is deionized water.

9. A method for anodic oxidizing a substrate, comprising the steps of:
preparing a substrate to be anodic oxidized for using as an anode;
placing said substrate and a cathode in an electrolyte so as to be electrifiable; and
irradiating said electrolyte by means of ultraviolet light before anodic oxidation of said substrate.
